(19) United States
(12) Patent Application Publication
(10) Pub. No.: US 2025/0004361 A1
(43) Pub. Date: Jan. 2, 2025

(54) OPTICAL PROXIMITY CORRECTION METHOD AND SEMICONDUCTOR FABRICATION METHOD USING THE SAME

(71) Applicant: Samsung Electronics Co., Ltd., Suwon-si (KR)

(72) Inventors: Woo-Yong Cho, Suwon-si (KR); Hun Kang, Suwon-si (KR); Sangwook Kim, Suwon-si (KR); Useong Kim, Suwon-si (KR); Heungsuk Oh, Suwon-si (KR); Hee-Jun Lee, Suwon-si (KR); Jeeeun Jung, Suwon-si (KR)

(21) Appl. No.: 18/437,779

(22) Filed: Feb. 9, 2024

(30) Foreign Application Priority Data
Jun. 30, 2023 (KR) 10-2023-0085157

(51) Int. Cl. G03F 1/36

(52) U.S. Cl. CPC G03F 1/36

(57) ABSTRACT

Disclosed are semiconductor fabrication methods and optical proximity correction (OPC) methods. The semiconductor fabrication method comprises performing OPC on a design pattern of a layout to generate a corrected layout, and forming a photoresist pattern on a substrate by using a photomask manufactured with the corrected layout. Performing the OPC includes generating shape points on a contour of the design pattern, producing a hash value of the shape point, selecting a first unique shape point that represents first shape points, determining a first correction bias of the first unique shape point, and creating a correction pattern by applying the first correction bias in common to the first shape points. Producing the hash value includes generating a query range around a target shape point and, based on geometry analysis in the query range, producing the hash value.

### CROSS-REFERENCE TO RELATED APPLICATION(S)

This U.S. nonprovisional application claims priority under 35 U.S.C. § 119 to Korean Patent Application No. 10-2023-0085157 filed on Jun. 30, 2023 in the Korean Intellectual Property Office, the disclosure of which is hereby incorporated by reference in its entirety.

### BACKGROUND

The present inventive concepts relate to a semiconductor fabrication method, and more particularly, to an optical proximity correction (OPC) method and a semiconductor fabrication method using the same.

Semiconductor devices have an important role in the electronic industry because of their small size, multi-functionality, and/or low fabrication cost. Semiconductor devices may encompass semiconductor memory devices storing logic data, semiconductor logic devices processing operations on logic data, and hybrid semiconductor devices having both memory and logic elements. Semiconductor devices have been increasingly required for high integration with the advanced development of the electronic industry. For example, semiconductor devices have been increasingly requested to have high reliability, high speed, and/or multi-functionality. Semiconductor devices are gradually becoming more complicated and more integrated to meet these requested characteristics.

### SUMMARY

Some embodiments of the present inventive concepts provide an optical proximity correction (OPC) method capable of reducing a time required for OPC.

Some embodiments of the present inventive concepts provide a method of fabricating a semiconductor device with increased integration and improved reliability.

According to some embodiments of the present inventive concepts, a semiconductor fabrication method may comprise: performing an optical proximity correction (OPC) step on a design pattern of a layout; and forming a photoresist pattern on a substrate by using a photomask manufactured with the corrected layout. The step of performing the OPC step may include: generating a plurality of shape points on a contour of the design pattern; producing a hash value with respect to each of the plurality of shape points; based on the hash value, selecting a first unique shape point from the plurality of shape points, wherein the first unique shape point represents first shape points; calculating a first correction bias of the first unique shape point; and creating a correction pattern by applying the first correction bias in common to the first shape points. The step of producing the hash value may include: generating a query range around a target shape point; and based on geometry analysis in the query range, producing the hash value.

According to some embodiments of the present inventive concepts, a semiconductor fabrication method may comprise: dividing a layout into a plurality of patches; generating a plurality of shape points in the plurality of patches; selecting a unique shape point from the plurality of shape points; selecting a target patch from the plurality of patches, the target patch including the unique shape point; performing an optical proximity correction (OPC) step on the target patch; and forming a photoresist pattern on a substrate by using a photomask manufactured with the layout that is corrected.

According to some embodiments of the present inventive concepts, an optical proximity correction method may comprise: performing a first optical proximity correction (OPC) step on a first layout; accumulating, in an OPC library, a first result of the first OPC step; selecting a unique patch from patches of a second layout, wherein the first result cannot be applied to the unique patch; performing a second OPC step on the unique patch; and accumulating, in the OPC library, a second result of the second OPC step. The first result may include a first correction bias with respect to a first unique shape point in the first layout. The second result may include a second correction bias with respect to a second unique shape point in the second layout.

### BRIEF DESCRIPTION OF DRAWINGS

FIG. 1 is a block diagram showing an example computer system for semiconductor design, according to some embodiments of the present inventive concepts.

FIG. 2 is a flow chart showing an example method of designing and fabricating a semiconductor device, according to some embodiments of the present inventive concepts.

FIG. 3 illustrates a conceptual diagram showing an example photolithography system that uses a photomask manufactured, according to some embodiments of the present inventive concepts.

FIG. 4 is a simplified flow chart showing detailed procedures of an example optical proximity correction method, according to some embodiments of the present inventive concepts.

FIGS. 5 and 6 are plan views showing an example designed layout.

FIGS. 7 to 18 are enlarged plan views of a region M of the example layout depicted in FIGS. 5 and 6, showing optical proximity correction, according to some embodiments of the present inventive concepts.

FIG. 19 is a plan view showing a photomask, according to some embodiments of the present inventive concepts.

FIG. 20 is a perspective view showing the formation of example photoresist patterns on a substrate by using a photomask of FIG. 19.

FIG. 21 is a simplified flow chart showing an example method of generating libraries of OPC results, according to some embodiments of the present inventive concepts.

FIG. 22 is a block diagram showing an example procedure in accordance with FIG. 21.

FIGS. 23 and 25 are plan views showing an example semiconductor fabrication method, according to some embodiments of the present inventive concepts.

FIGS. 24A, 24B, 24C, and 24D are cross-sectional views respectively taken along lines A-A′, B-B′, C-C′, and D-D′ of FIG. 23.

FIGS. 26A, 26B, 26C, and 26D are cross-sectional views respectively taken along lines A-A′, B-B′, C-C′, and D-D′ of FIG. 25.

### DETAILED DESCRIPTION OF EMBODIMENTS

Illustrative embodiments of the inventive concepts will be described herein with reference to the accompany drawings, wherein like reference numerals (when used) indicate corresponding elements throughout the several views.

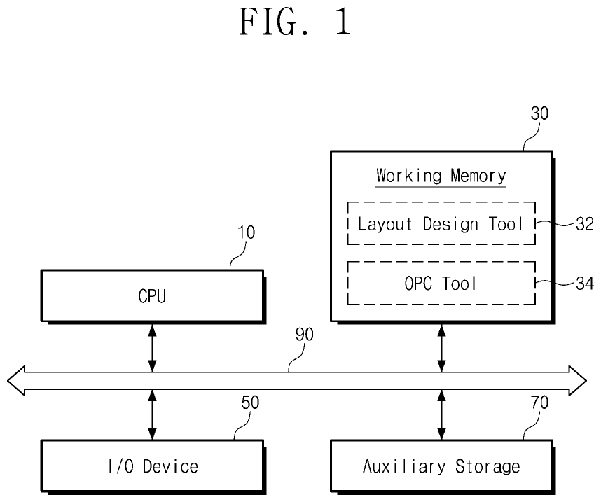

FIG. 1 illustrates a block diagram showing an example computer system for semiconductor design, according to some embodiments of the present inventive concepts. Referring to FIG. 1, a computer system may include a central processing unit (CPU) 10, a working memory 30, an input/output (I/O) device 50, and an auxiliary storage 70 (e.g., a non-transitory storage medium). The computer system may be provided as a dedicated device for designing a layout of the present inventive concepts. The computer system may be configured to drive various design and verification simulation programs.

The CPU 10 may be configured to allow the computer system to execute software (e.g., application programs, operating system, and device drivers). The CPU 10 may process (i.e., execute) an operating system loaded in the working memory 30. The CPU 10 may execute various application programs driven based on the operating system (OS). For example, the CPU 10 may process a layout design tool 32 and/or an optical proximity correction (OPC) tool 34 that are loaded in the working memory 30.

The operating system (OS) or application programs may be loaded into the working memory 30. When the computer system is booted up, based on a booting sequence, an operating system image (not shown) stored in the auxiliary storage 70 may be loaded into the working memory 30. Overall input/output operations of the computer system may be supported by the operating system (OS). The working memory 30 may be loaded with the application programs that are selected by a user or provided for a basic service. The layout design tool 32 and/or the OPC tool 34 may be loaded from the auxiliary storage 70 to the working memory 30.

The layout design tool 32 may include a bias function configured to generate changed bias data by which specific layout patterns are changed in shapes and/or positions defined by a design rule. In addition, the layout design tool 32 may perform a design rule check (DRC) under the changed bias data condition. The OPC tool 34 may perform optical proximity correction (OPC) on layout data output from the layout design tool 32. The working memory 30 may be either a volatile memory such as static random access memory (SRAM) and dynamic random access memory (DRAM) or a nonvolatile memory such as phase change random access memory (PRAM), magnetic random access memory (MRAM), resistance random access memory (ReRAM), ferroelectric random access memory (FRAM), and NOR Flash memory.

The input/output device 50 may control user input/output operations of user interfaces. For example, the input/output device 50 may include a keyboard or a monitor, allowing a designer to enter relevant information. The user may use the input/output device 50 to receive information about a semiconductor region or data paths requiring adjusted operating characteristics. The input/output device 50 may display a progress status or a process result of the OPC tool 34.

The auxiliary storage 70 may serve as a non-transitory storage medium for the computer system. The auxiliary storage 70 may store the application programs, the operating system image, and various data. The auxiliary storage 70 may be provided in the form of, for example, one of memory cards (e.g., multimedia card (MMC), embedded multimedia card (eMMC), secure digital (SD) card, and Micro SD card) and a hard disk drive (HDD). The auxiliary storage 70 may include a NAND Flash memory having large memory capacity. Alternatively, the auxiliary storage 70 may include a NOR Flash memory or a next-generation volatile memory such as PRAM, MRAM, ReRAM, and FRAM.

A system interconnector 90 may be provided to serve as a system bus for providing a network in the computer system. The CPU 10, the working memory 30, the input/output device 50, and the auxiliary storage 70 may be electrically connected through the system interconnector 90 and may exchange data with each other. The system interconnector 90 is not limited to the above description, and may further include intermediary means for efficient management. The system interconnector 90 maybe wired, wireless, or a hybrid combination of wired and wireless.

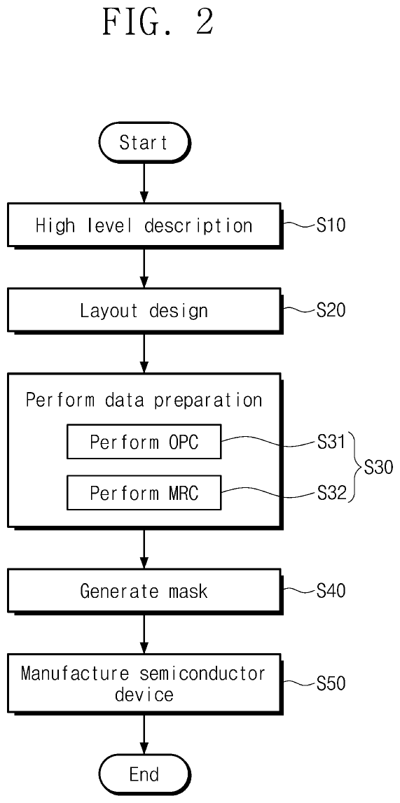

FIG. 2 is a flow chart showing an example method of designing and fabricating a semiconductor device, according to some embodiments of the present inventive concepts. Referring to FIG. 2, a high-level design of a semiconductor integrated circuit may be performed using, for example, the computer system discussed with reference to FIG. 1 (S10). The high-level design may mean that an integrated circuit corresponding to a design target is described with a high-level language of a hardware description language (HDL). For example, the high-level language such as C language may be used in the high level design. A register transfer level (RTL) coding or simulation may be used to express in detail circuits designed by the high-level design. In addition, codes created by the register transfer level coding may be converted into a netlist, which netlist may be synthesized to describe an entire semiconductor device. The synthesized schematic circuit may be verified by a simulation tool, and an adjustment process may be performed based on the verified result.

A layout design may be performed to implement on a silicon substrate a semiconductor integrated circuit that is logically completed (S20). For example, the layout design step may be performed based on the schematic circuit synthesized in the high-level design step or the netlist corresponding to the schematic circuit. The layout design step may include a routing step that places and connects various standard cells provided from a cell library, based on a prescribed design rule (e.g., a place-and-route process). A place-and-route process places each cell from a synthesis netlist into an available region on a target silicon substrate and generates interconnects for the cells using routing resources available on the target silicon substrate.

A cell library for the layout design may include information about operation, speed, and power consumption of the standard cell. The cell library for representing a layout of a specific gate-level circuit as a layout may be defined in the layout design tool. The layout may be prepared to define shapes or dimensions of patterns constituting transistors and metal lines that will be actually formed on a silicon substrate. For example, in order to actually form an inverter circuit on a silicon substrate, it may be necessary to appropriately place or describe layout patterns such as PMOS, NMOS, N-WELL, gate electrodes, and metal lines thereon. For this, a search may be first performed to select a suitable one of inverters predefined in the cell library.

Thereafter, a routing step of connecting the selected and provided standard cells may be performed. Specifically, a routing step may be performed to connect the selected and placed standard cells to their overlying lines. The standard cells may be well-designed to facilitate connection to each other through the routing step. A series of these steps may be automatically or manually performed in the layout design tool. A step of placing and routing the standard cells may be automatically performed by an additional Place & Routing tool.

After the routing step, a verification step may be performed on the layout to check whether any portion of the schematic circuit violates the given design rule for the particular fabrication process. The verification step may include a design rule check (DRC) for verifying whether the layout meets the given design rule, an electrical rule check (ERC) for verifying whether there is an issue of an electrical disconnection or electrical short in the layout, and a layout vs. schematic (LVS) for verifying whether the layout agrees with the gate-level netlist.

A data preparation (DP) step may be performed to obtain mask data from the designed layout (S30). The data preparation step may include performing an optical proximity correction (OPC) step on a designed layout (S31) and performing a mask rule check (MRC) step on the OPC result (S32).

A photolithography process may be employed to achieve, on a silicon substrate, the layout patterns obtained by the layout design step. The optical proximity correction may be a technique for correcting an unintended optical effect that occurs in the photolithography process, or to generally compensate for the non-ideal behavior of light that may occur during photolithography. For example, the optical proximity correction may correct an undesirable phenomenon, such as refraction, reflections, or process side-effects caused by characteristics of light in an exposure process using the layout patterns. When the optical proximity correction step is performed, the designed layout patterns may be slightly changed (or biased) in shapes and/or positions.

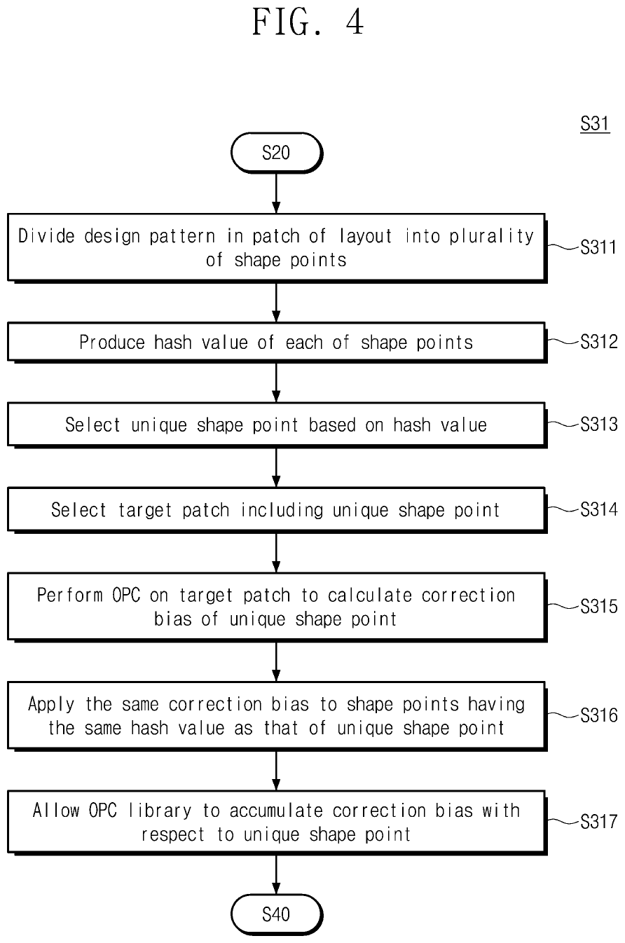

An MRC may be performed to verify whether the OPC-modified patterns meet the given design rule (S32). A pattern that does not meet the mask rule may be corrected to obtain a clean-up result so that every mask rule error is eliminated. The clean-up result may be obtained from mask data that has experienced the data preparation step S30. With reference to FIGS. 4 to 11, the following will describe in detail the data preparation step S30 according to the present inventive concepts.

The data preparation step S30 may be employed to generate a photomask (S40). The photomask may generally be manufactured by describing the layout patterns using a chromium layer coated on a glass substrate, although embodiments are not limited thereto.

The generated photomask may be used to manufacture a semiconductor device (S50). Various exposure and etching processes may be repeatedly performed in manufacturing the semiconductor device using the photomask. Through these processes discussed above, patterns defined in the layout design may be sequentially formed on a silicon substrate.

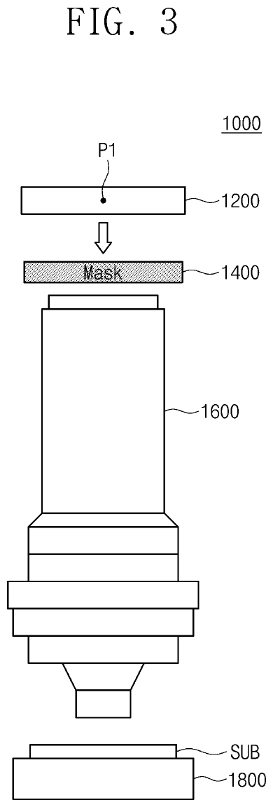

FIG. 3 illustrates a conceptual diagram showing a photolithography system 1000 that uses a photomask manufactured according to some embodiments of the present inventive concepts. The photolithography system 1000 may include a light source 1200, a photomask 1400, a reduction projection apparatus 1600, and a substrate stage 1800. The photolithography system 1000 may further include components that are not shown in FIG. 3. For example, the photolithography system 1000 may further include a sensor used for measuring height and slope of a surface of a substrate SUB on the substrate stage 1800.

The light source 1200 may emit light. The light emitted from the light source 1200 may travel toward the photomask 1400. For example, the light source 1200 and the photomask 1400 may be provided therebetween with a lens to adjust a focus of the light. The light source 1200 may include an ultraviolet light source (e.g., a krypton fluoride (KrF) light source with wavelength of 234 nanometers (nm), an argon fluoride (ArF) light source with wavelength of 193 nm), or an extreme ultraviolet (EUV) light source. The light source 1200 may include a single point light source P1, but the present inventive concepts are not limited thereto. In some embodiments, the light source 1200 may include a plurality of point light sources.

The photomask 1400 may include image patterns to print (implement) the designed layout on the substrate SUB. The image patterns may be formed based on the mask data that are obtained through the data preparation step (S30 of FIG. 2) discussed above. The image patterns may be defined by a transparent region and an opaque region. The transparent region may be formed by etching a metal layer (e.g., a chromium layer) on the photomask 1400. The transparent region may be transparent to the light emitted from the light source 1200. In contrast, the opaque region may block the light without allowing the light to pass therethrough.

The reduction projection apparatus 1600 may receive light that passes through the transparent region of the photomask 1400. The reduction projection apparatus 1600 may match layout patterns, which will be printed on the substrate SUB, with the image patterns of the photomask 1400. The substrate SUB may be irradiated with the light that passes through the reduction projection apparatus 1600. Therefore, the substrate SUB may be printed thereon with patterns that correspond to the image patterns of the photomask 1400.

The substrate stage 1800 may support the substrate SUB. For example, the substrate SUB may include a silicon wafer. The reduction projection apparatus 1600 may include an aperture. The aperture may be used to raise a depth of focus of an ultraviolet ray emitted from the light source 1200. For example, the aperture may include a dipole aperture or a quadruple aperture. The reduction projection apparatus 1600 may further include a lens to adjust a focus of light.

An increase in integration of semiconductor devices may relatively decrease a distance between the image patterns of the photomask 1400. Such “proximity” may induce interference and diffraction of light, and a distorted pattern may be printed on the substrate SUB. When distorted patterns are printed on the substrate SUB, designed circuits may abnormally operate or not operate at all.

A resolution enhancement technology may be used to prevent a pattern distortion. The optical proximity correction (see S31 of FIG. 2) may be an example of the resolution enhancement technology. According to the optical proximity correction, it may be possible to predict the degree of distortion such as interference and diffraction of light. Based on predicted results, a designed layout may be changed (biased). Based on the changed layout, image patterns may be formed on the photomask 1400, and desired patterns may then be printed on the substrate SUB.

A layout of a semiconductor device may include a plurality of layers. For example, the optical proximity correction may be performed to adjust a layout of a single layer. To be specific, the optical proximity correction may be independently performed on each of the plurality of layers. The plurality of layers may be sequentially implemented through semiconductor processes on a substrate to form a semiconductor device. For example, a semiconductor device may include a plurality of stacked metal layers to achieve a specific circuit.

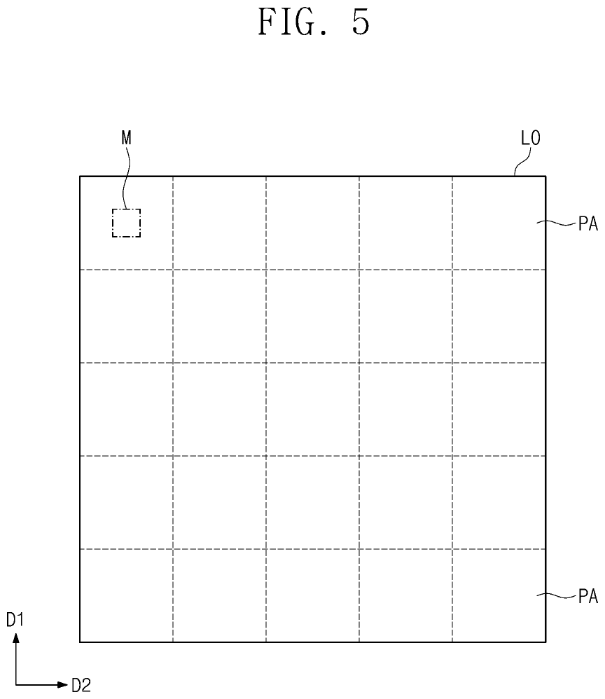

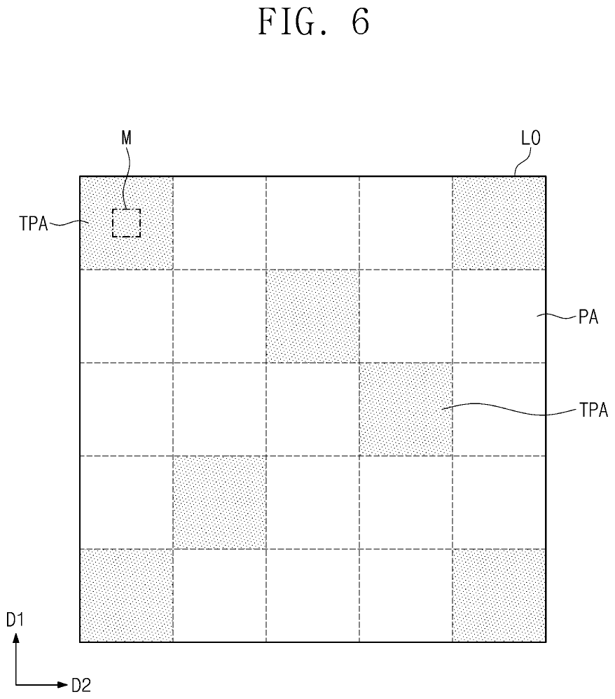

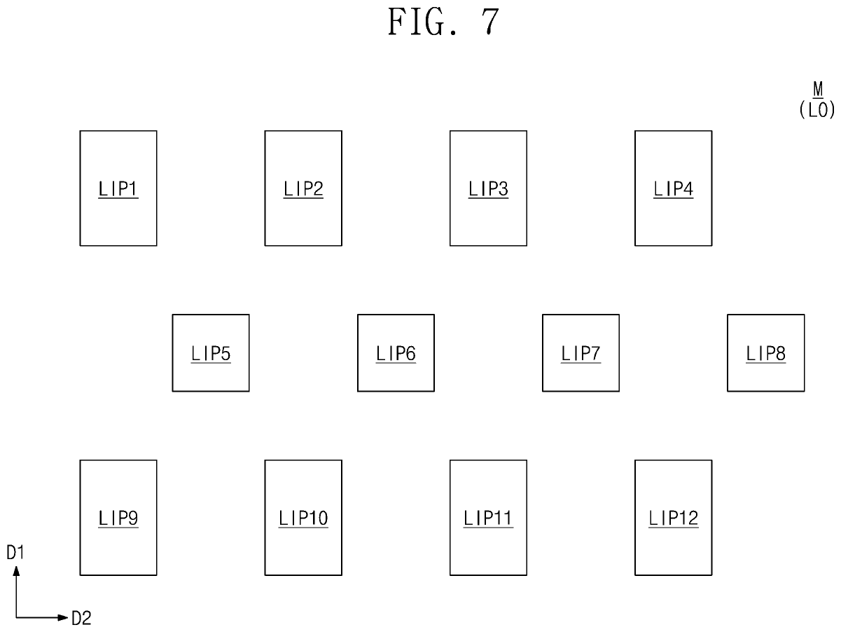

FIG. 4 is a simplified flow chart showing detailed procedures of an example optical proximity correction process S31, according to some embodiments of the present inventive concepts. FIGS. 5 and 6 are plan views showing an example designed layout. FIGS. 7 to 18 are enlarged plan views of a region M depicted in FIGS. 5 and 6, showing optical proximity correction, according to some embodiments of the present inventive concepts.

Referring to FIGS. 4, 5, and 7, a layout LO may be provided which is generated through the layout design step S20 discussed above. The layout LO may be a single-layered layout. In accordance with a proximity environment and type of unit device, the layout LO may be divided into a plurality of patches (i.e., regions) PA. The patches PA may be two-dimensionally arranged. For example, the patches PA may have the same size relative to one another.

A plurality of patches PA may be correspondingly provided on a plurality of nodes of the OPC tool (see 34 of FIG. 1). Optical proximity correction (OPC) may be performed in parallel (i.e., concurrently) on the plurality of patches PA through the plurality of nodes of the OPC tool 34 (FIG. 1). Each of the patches PA may be a basic unit on which the optical proximity correction is performed.

A single patch PA may include a plurality of design patterns LIP. For example, a region M of the designed layout of FIG. 5 depicted in FIG. 7 may include first to twelfth design patterns LIP1 to LIP12. According to the present embodiment, each of the first to twelfth design patterns LIP1 to LIP12 may be an island pattern. Each of the first to twelfth design patterns LIP1 to LIP12 may have a tetragonal shape. The first to twelfth design patterns LIP1 to LIP12 may be two-dimensionally arranged on the layout LO according to a first direction D1 and a second direction D2, the first and second directions D1 and D2 being parallel to an upper surface of the substrate SUB (i.e., horizontal) and intersecting one another.

A shape of the designed layout LO shown in FIG. 7 may be an example to facilitate an understanding of the present inventive concepts, but the present inventive concepts are not limited thereto. The layout LO may be provided as an initially designed layout. The first to twelfth design patterns LIP1 to LIP12 shown in FIG. 7 may express target patterns which are intended to be implemented (i.e., formed) on the substrate SUB.

A data preparation step (see S30 of FIG. 2) may be performed on the patches PA including the first to twelfth design patterns LIP1 to LIP12. The data preparation step may include performing an optical proximity correction (OPC) step on a designed layout (see S31 of FIG. 2) and performing a mask rule check (MRC) step on the OPC result (see S32 of FIG. 2).

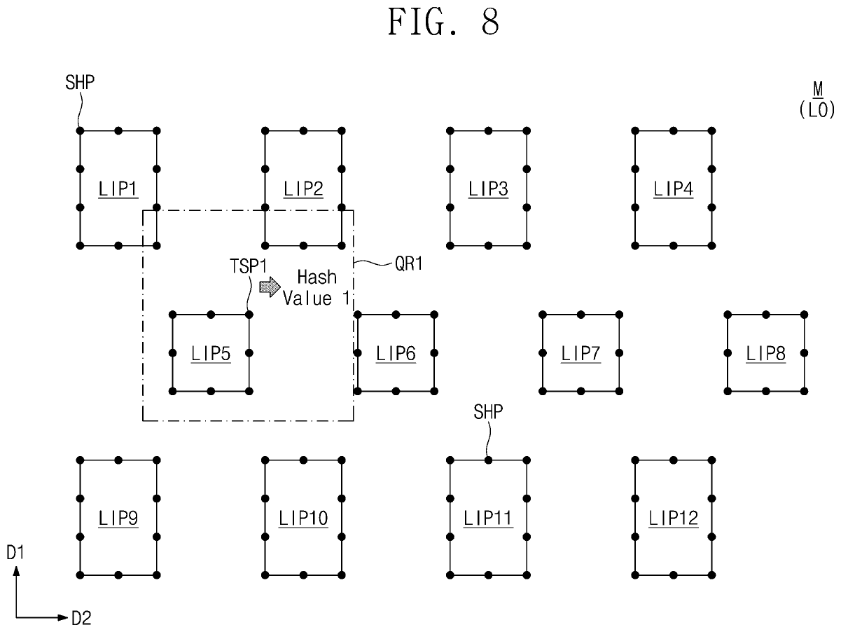

Referring to FIGS. 4 and 8, each of the first to twelfth patterns LIP1 to LIP12 may be divided into a plurality of shape points SHP (S311). The shape points SHP may be generated on a contour of each of the first to twelfth design patterns LIP1 to LIP12. In an embodiment, the shape points SHP may be generated at a regular interval on each of the first to twelfth design patterns LIP1 to LIP12.

A hash value may be produced for each of the shape points SHP (S312). For example, a hash value may be produced for a first target point TSP1, or a certain one of the shape points SHP. The following will describe a method of producing hash values of target points.

There may be generated a first query range QR1 around the first target point TSP1, as shown in FIG. 8. For example, the first query range QR1 may be a peripheral area capable of optically affecting the first target point TSP1. The first query range QR1 may include not only the first target point TSP1 but also other shape points SHP around the first target point TSP1.

A hash value may be produced through a geometry analysis in the first query range QR1. The geometry analysis may be performed on the basis of information about a pattern image in the first query range QR1. For example, the information about the pattern image may include the number of the shape points SHP around the first target point TSP1, a contour that connects the shape points SHP to each other, and distances between the first target point TSP1 and the shape points SHP.

A hash value of the first target point TSP1 may be produced as a 64-bit unique value, although embodiments are not limited thereto. The hash value of the first target point TSP1 may be a hash ID of the first target point TSP1. For example, the hash value of the first target point TSP1 may be produced as Hash Value 1.

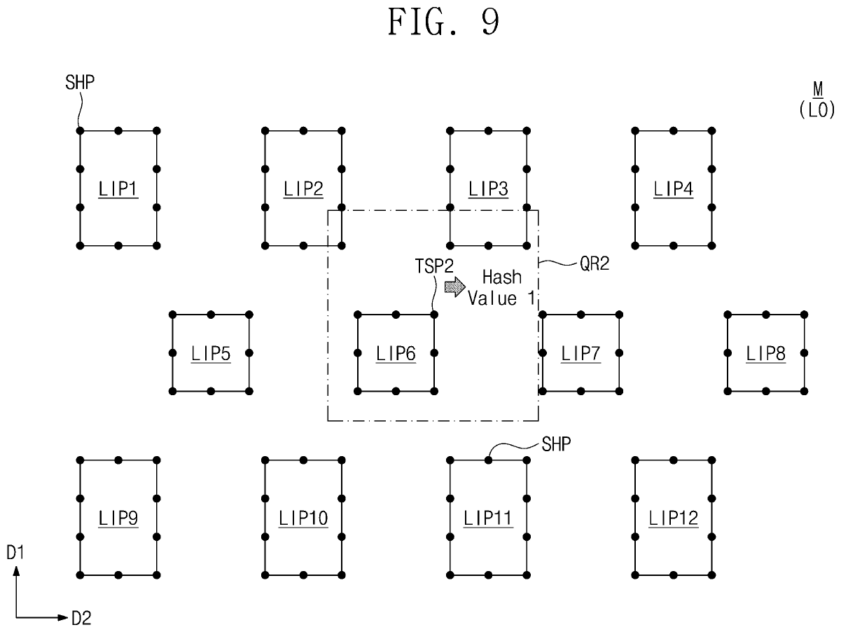

Referring to FIGS. 4 and 9, a hash value of a second target point TSP2 may be produced (S312). There may be created a second query range QR2 around the second target point TSP2. A geometry analysis of the second query range QR2 may create the hash value of the second target point TSP2. According to the present embodiment, the second query range QR2 may have a pattern image the same as that of the first query range QR1. Therefore, the hash value of the second target point TSP2 may be produced as Hash Value 1, the same as the hash value of the first target point TSP1.

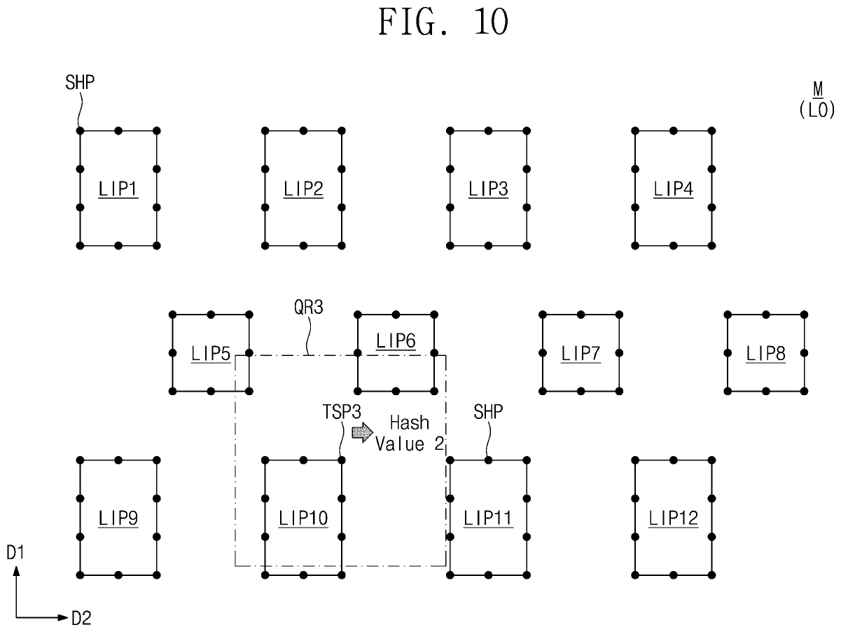

Referring to FIGS. 4 and 10, a hash value of a third target point TSP3 may be produced (S312). There may be created a third query range QR3 around the third target point TSP3. A geometry analysis of the third query range QR3 may create the hash value of the third target point TSP3. According to the present embodiment, the third query range QR3 may have a pattern image different from that of the first query range QR1. Therefore, the hash value of the third target point TSP3 may be produced as Hash Value 2, different from the hash value of the first target point TSP1.

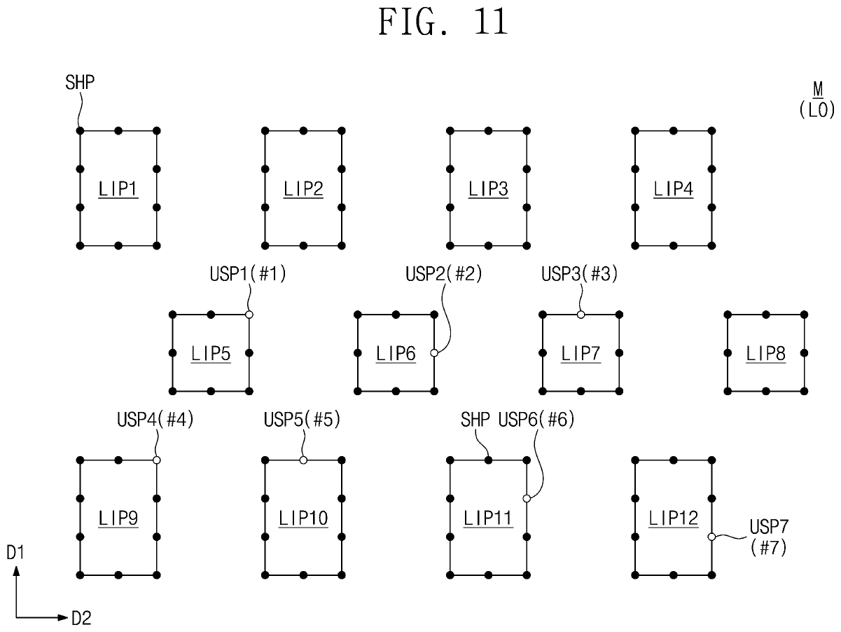

Referring to FIGS. 4 and 11, a unique shape point USP may be selected on the basis of hash points of the shape points SHP (S313). A representative one of the shape points SHP having the same hash value may be selected as the unique shape point USP.

For example, the first target point TSP1 of FIG. 8 and the second target point TSP2 of FIG. 9 may have the same value, or Hash Value 1. Thus, the first target point TSP1 representative of one of the shape points SHP may be selected as a first unique shape point USP1. Seven shape points USP may be selected in the region M of the layout LO according to the present embodiment.

The unique shape points USP of FIG. 11 may include first to seventh unique shape points USP1 to USP7. The first to seventh unique shape points USP1 to USP7 may have their respective first to seventh hash values #1 to #7 that are different from each other.

Referring to FIGS. 4 and 6, a patch among the patches PA that includes the unique shape point USP may be selected as a target patch TPA (S314). For example, seven patches of twenty five patches PA may be selected as the target patches TPA. The OPC may be performed only on the unique shape points USP in the seven target patches TPA. The OPC of the present inventive concepts may not be performed on all of the shape points SHP in all of the patches PA. As the OPC of the present inventive concepts is selectively performed on a unique shape point in a target patch, it may be possible to maintain consistency of OPC and to dramatically reduce a time required for performing OPC.

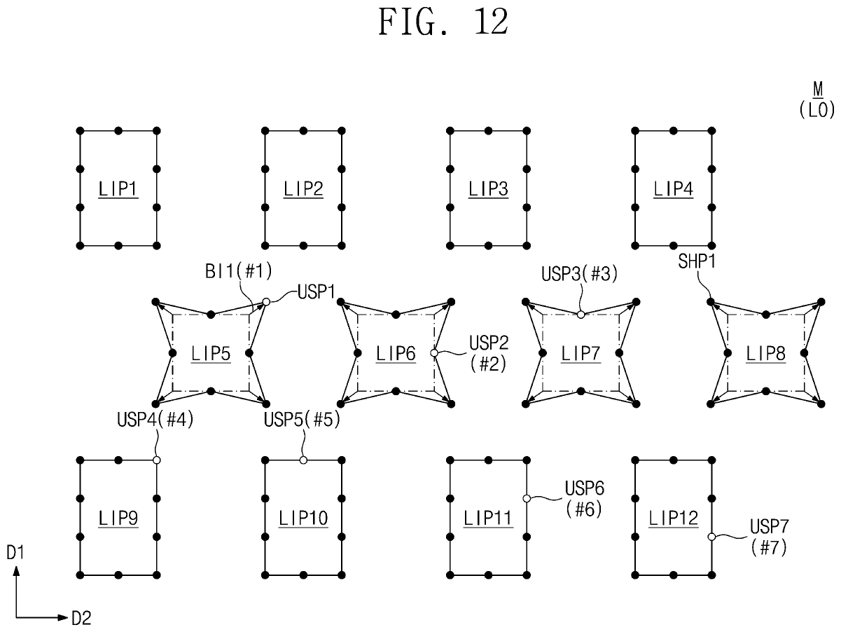

Referring to FIGS. 4 and 12, the OPC tool (see 34 of FIG. 1) may be used to calculate a first bias BI1 which will be applied to the first unique shape point USP1 (S315). The first bias BI1 may include information about a correction vector of a shape point. The first bias BI1 may include information about a movement direction (or angle) and a movement distance (i.e., offset) of the shape point from an original position of the shape point.

When the OPC tool (see 34 of FIG. 1) performs the OPC according to the present inventive concepts, the same correction bias may be applied to the shape points SHP having the same hash value. The first bias BI1 may be applied in common to first shape points SHP1 each having the first hash value #1 the same as that of the first unique shape point USP1. Therefore, the first shape points SHP1 may be biased (or changed) as much as the first bias BI1.

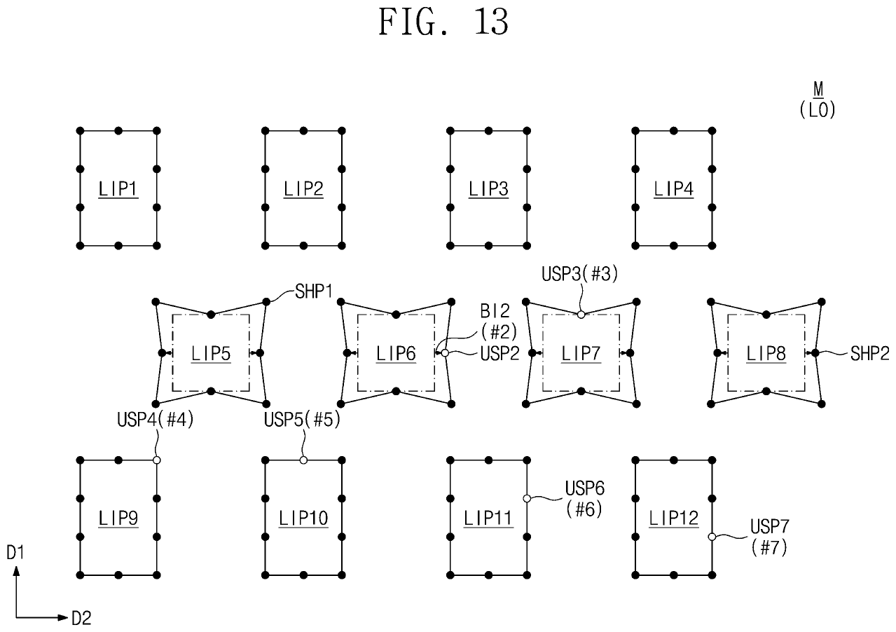

Referring to FIGS. 4 and 13, the OPC tool (see 34 of FIG. 1) may be used to calculate a second bias BI2 which will be applied to the second unique shape point USP2 (S315). The second bias BI2 may be applied in common to second shape points SHP2 each having the second hash value #2 the same as that of the second unique shape point USP2 (S316). Therefore, the second shape points SHP2 may be biased (or changed) as much as the second bias BI2. In an embodiment, the second bias BI2 may have an angle and a distance different from those of the first bias BI1 of FIG. 12.

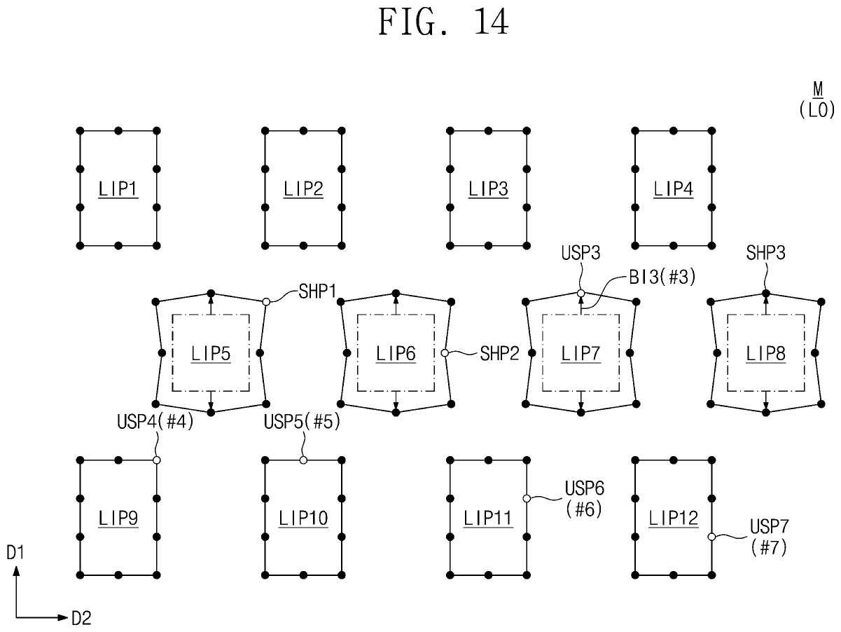

Referring to FIGS. 4 and 14, the OPC tool (see 34 of FIG. 1) may be used to calculate a third bias BI3 which will be applied to the third unique shape point USP3 (S315). The third bias BI3 may be applied in common to third shape points SHP3 each having the third hash value #3 the same as that of the third unique shape point USP3 (S316). Therefore, the third shape points SHP3 may be biased (or changed) as much as the third bias BI3.

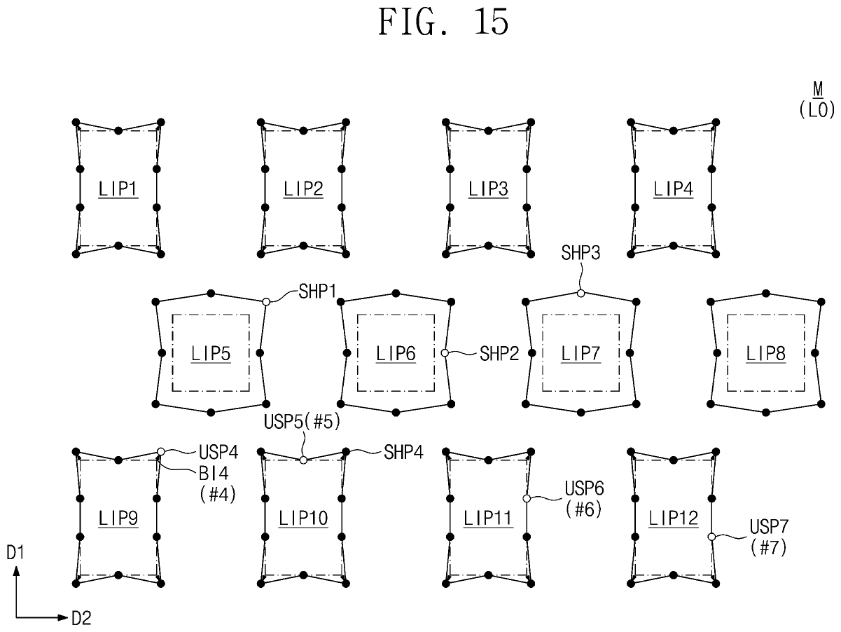

Referring to FIGS. 4 and 15, the OPC tool (see 34 of FIG. 1) may be used to calculate a fourth bias BI4 which will be applied to the fourth unique shape point USP4 (S315). The fourth bias BI4 may be applied in common to fourth shape points SHP4 each having the fourth hash value #4 the same as that of the fourth unique shape point USP4 (S316). Therefore, the fourth shape points SHP4 may be biased (or changed) as much as the fourth bias BI4.

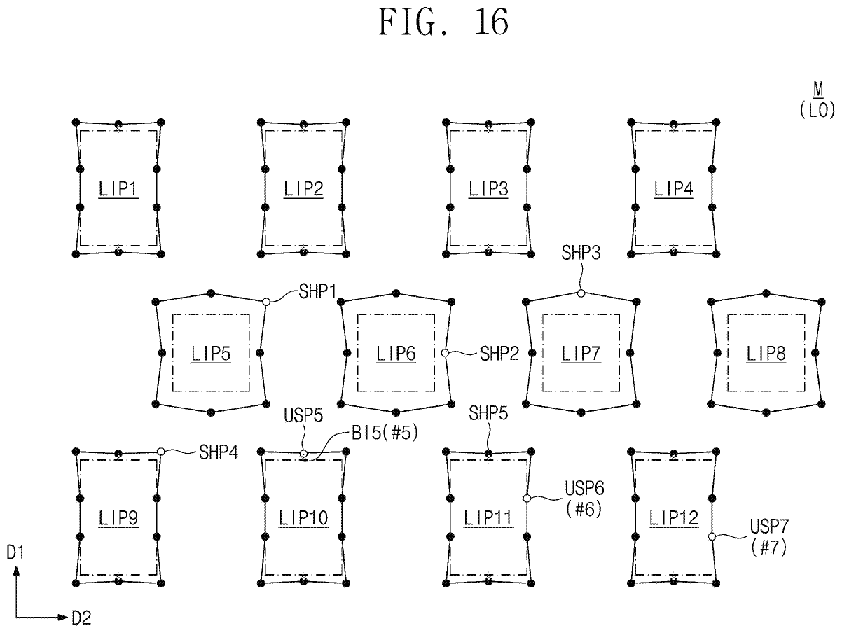

Referring to FIGS. 4 and 16, the OPC tool (see 34 of FIG. 1) may be used to calculate a fifth bias BI5 which will be applied to the fifth unique shape point USP5 (S315). The fifth bias BI5 may be applied in common to fifth shape points SHP5 each having the fifth hash value #5 the same as that of the fifth unique shape point USP5 (S316). Therefore, the fifth shape points SHP5 may be biased (or changed) as much as the fifth bias BI5.

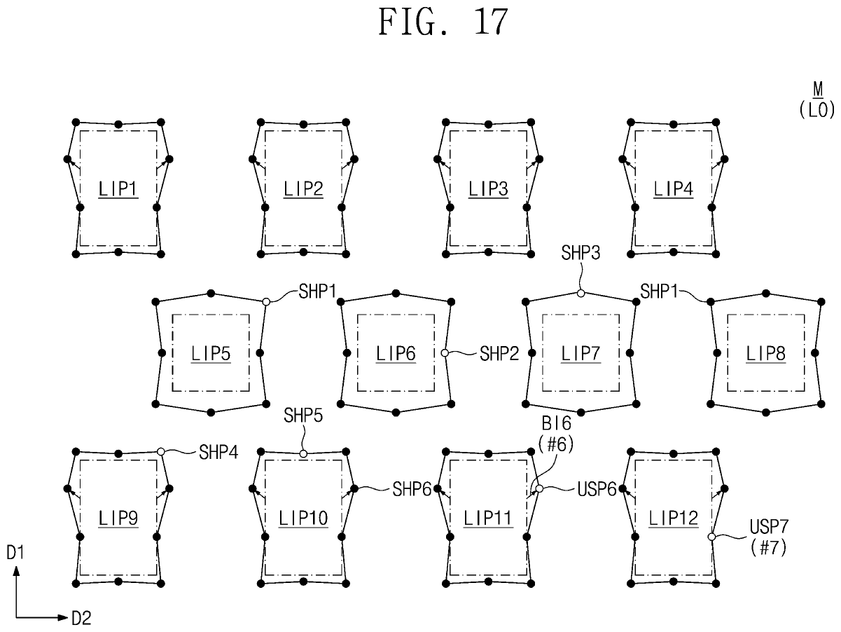

Referring to FIGS. 4 and 17, the OPC tool (see 34 of FIG. 1) may be used to calculate a sixth bias BI6 which will be applied to the sixth unique shape point USP6 (S315). The sixth bias BI6 may be applied in common to sixth shape points SHP6 each having the sixth hash value #6 the same as that of the sixth unique shape point USP6 (S316). Therefore, the sixth shape points SHP6 may be biased (or changed) as much as the sixth bias BI6.

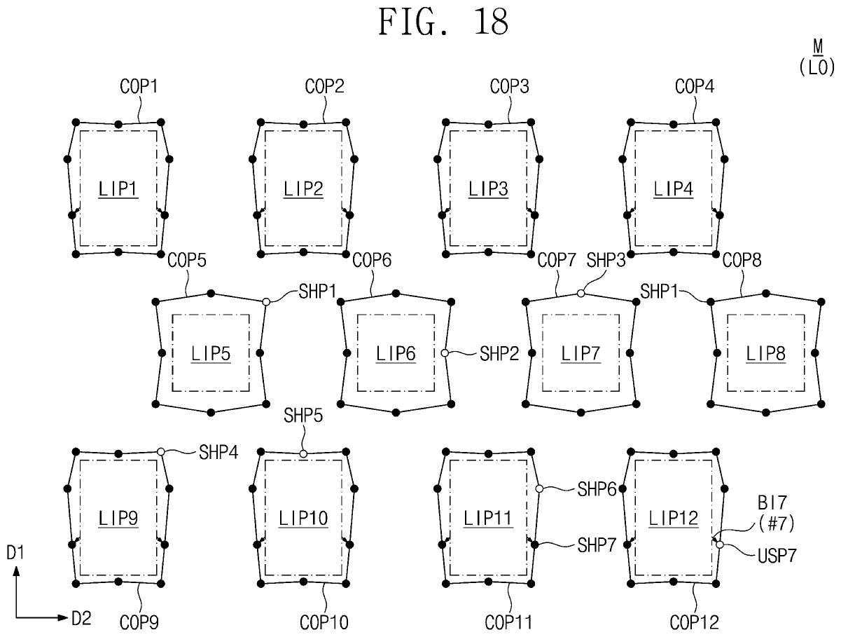

Referring to FIGS. 4 and 18, the OPC tool (see 34 of FIG. 1) may be used to calculate a seventh bias BI7 which will be applied to the seventh unique shape point USP7 (S315). The seventh bias BI7 may be applied in common to seventh shape points SHP7 each having the seventh hash value #7 the same as that of the seventh unique shape point USP7 (S316). Therefore, the seventh shape points SHP7 may be biased (or changed) as much as the seventh bias BI7.

Through the procedures discussed above, a correction bias may be applied to all of the shape points SHP. In the present inventive concepts, no correction bias may be independently calculated and applied to each of the shape points SHP. When each of the shape points SHP is independently corrected, there may be an increase in time required for performing OPC. According to some embodiments of the present inventive concepts, a correction bias of the unique shape point USP may be representatively calculated, and the correction bias may be applied in common to the shape points SHP each having the same hash value as that of the unique shape point USP. Accordingly, it may be possible to dramatically reduce a time required for performing the optical proximity correction.

The corrected shape points SHP may constitute a correction pattern COP. For example, the first to seventh design patterns LIP1 to LIP12 may undergo the optical proximity correction to respectively create first to twelfth correction patterns COP1 to COP12. In the present embodiment, there is illustrated an OPC step at the target patch TPA of FIG. 6. However, the step of applying a correction bias to shape points each having the same hash value as that of a unique shape point (S316) may be applied in common to all of the patches PA depicted in FIG. 6.

An OPC library may store the correction biases BI1 to BI7 applied to the unique shape points USP1 to USP7 performed on the target patches TPA (S317). For example, an OPC result in accordance with unique hash values of the unique shape points USP1 to USP7 may be stored in the form of a table in the OPC library. Afterwards, when the OPC step is performed on another layout, the result stored in the OPC library may be loaded to the other layout. Accordingly, it may be possible to increase efficiency of the OPC step.

When correction patterns COP are generated for the design patterns LIP in the layout LO, a mask rule check (MRC) step may be performed on the created correction patterns COP (sec S32 of FIG. 2). The correction patterns COP may be additionally corrected through the MRC step, and thus it may be possible to solve all mask rule violations. Accordingly, the data preparation step may be terminated, and a final result may be output as mask data.

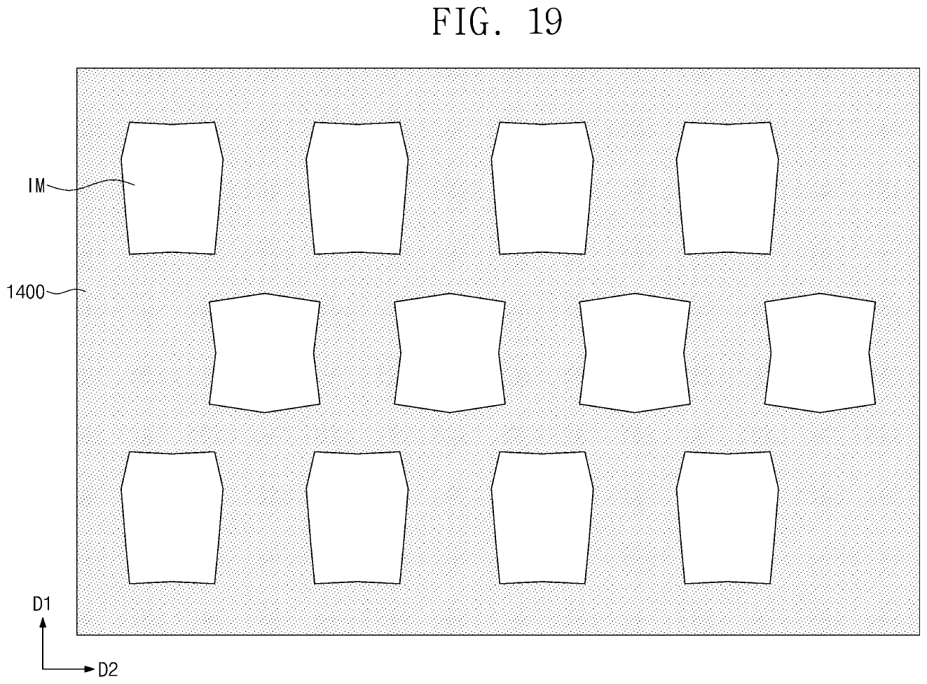

FIG. 19 is a plan view showing an example photomask according to some embodiments of the present inventive concepts. Referring to FIGS. 2 and 19, the photomask 1400 may be manufactured based on the final correction patterns COP, for example, the first to twelfth correction patterns COP1 to COP12 (see S40 of FIG. 2). The photomask 1400 may include image patterns IM. The image patterns IM may be formed based on the correction patterns COP in the layout LO discussed in the present embodiment.

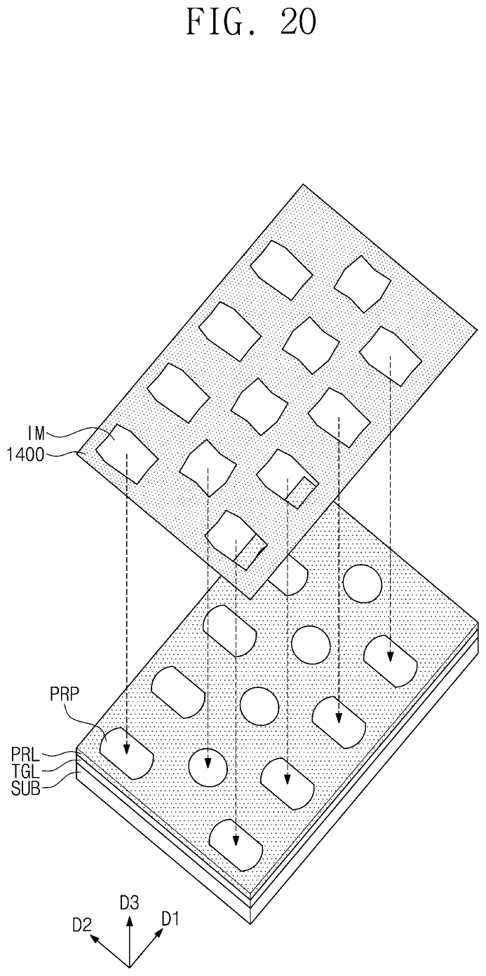

FIG. 20 is a perspective view conceptually showing the formation of photoresist patterns on a substrate by using a photomask of FIG. 19. Referring to FIG. 20, the light source 1200 of FIG. 3 may emit light to the photomask 1400. The emitted light may pass through transparent regions of the image patterns IM, and then may travel toward a photoresist layer PRL on the substrate SUB (an exposure process). A region where the light is irradiated in the photoresist layer PRL may be converted into a photoresist pattern PRP. The photoresist patterns PRP may be formed to have shapes and sizes similar to those of the design patterns LIP discussed above in FIG. 7.

A development process may be subsequently performed to leave the photoresist patterns PRP and to remove the photoresist layer PRL. The remaining photoresist patterns PRP may be used as an etching mask to pattern an etch target layer TGL on the substrate SUB. Thus, target patterns may be implemented on the substrate SUB. As a result, the aforementioned method may implement target patterns on each layer to fabricate a semiconductor device (see S50 of FIG. 2).

According to an embodiment of the present inventive concepts, the patterning process for forming the photoresist pattern PRP may include an extreme ultraviolet (EUV) lithography process. The EUV lithography process may include exposure and development processes that use an extreme ultraviolet (EUV) radiation irradiated to a photoresist layer. For example, the photoresist layer may be an organic photoresist that contains an organic polymer such as polyhydroxystyrene. The organic photoresist may further include a photosensitive compound sensitive to the EUV. The organic photoresist may additionally include a material whose EUV absorption coefficient is high, for example, an organometallic material, an iodine-containing material, or a fluorine-containing material. For another example, the photoresist layer may be an inorganic photoresist that contains an inorganic material, such as tin oxide.

The photoresist layer may be formed relatively thin. The photoresist layer exposed to the EUV may undergo a development process to form photoresist patterns. When viewed in plan, the photoresist patterns may have a linear shape that extends in one direction, an island shape, a zigzag shape, a honeycomb shape, or a circular shape, but the present inventive concepts are not limited to a particular example.

The photoresist patterns may be used as an etching mask to pattern one or more mask layers that are stacked below the photoresist patterns, and thus mask patterns may be formed. The mask patterns may be used as an etching mask to pattern the etch target layer TGL to form a target pattern on the substrate SUB.

A value equal to or less than about 45 nm may be given as a minimum pitch between target patterns achieved by the EUV lithography process of the present embodiment. For example, the EUV lithography process may be performed in which only one photomask is enough to accomplish the target patterns that are elaborate and delicate.

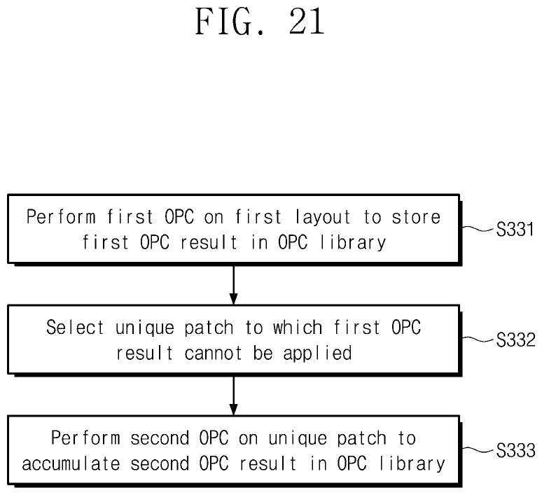

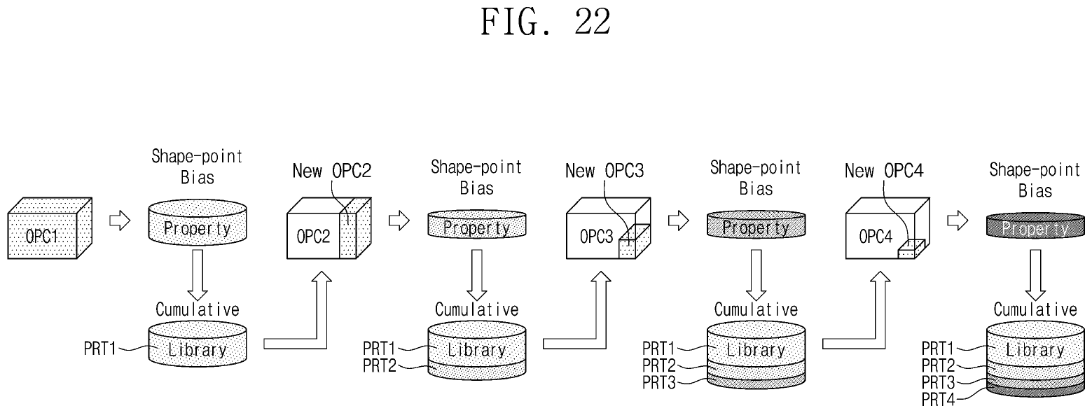

FIG. 21 is a simplified flow chart showing an example method of generating a library of OPC results, according to some embodiments of the present inventive concepts. FIG. 22 is a conceptual block diagram showing an example procedure in accordance with FIG. 21.

Referring to FIGS. 21 and 22, through a first OPC procedure OPC1 discussed above with reference to FIGS. 4 to 18 according to the present inventive concepts, a first OPC result PRT1 with respect to a first unique shape point may be stored (or accumulated) in an OPC library (S331). For example, the first OPC result PRT1 may include a table related to a correction bias in accordance with a unique hash value of the first unique shape point. The first OPC procedure OPC1 may be performed on all of the patches PA of the layout LO depicted in FIG. 5.

A second OPC procedure OPC2 may be performed on a second layout. For example, the first OPC result PRT1 stored (or accumulated) in the OPC library may be loaded to the second layout. The second layout may include a normal patch including the first unique shape point included in the first OPC result PRT1 and a unique patch including a new second unique shape point to which the first OPC result PRT1 cannot be applied. Thus, a procedure may be first performed in which the unique patch is searched and selected (S332). In the present embodiment, the unique patch may be similar to the target patch TPA in the step S314 discussed above with reference to FIGS. 4 and 6.

The second OPC procedure OPC2 may be performed on the selected unique patch. The second OPC step performed on the selected unique patch may be substantially the same as a procedure discussed above with reference to FIGS. 4 to 18. The second OPC procedure OPC2 may allow the OPC library to accumulate a second OPC result PRT2 with respect to the second unique shape point (S333).

Afterward, whenever an additional OPC step is performed on an additional layout, the steps S332 and S333 may be repeatedly performed. Thus, whenever the OPC is performed, an OPC result may be continuously accumulated in the OPC library (PRT1 to PRT4 of FIG. 22).

In an OPC step according to some embodiments of the present inventive concepts, a design pattern may be divided into shape points, and the shape points may be corrected to create a free-form correction pattern. There may thus be an increase in accuracy of OPC.

In an OPC step according to some embodiments of the present inventive concepts, a unique shape point may be searched and selected, and OPC may be performed only on a target patch including the unique shape point. Accordingly, it may be possible to maintain consistency of optical proximity correction and to dramatically reduce a time required for performing optical proximity correction.

In an OPC step according to some embodiments of the present inventive concepts, whenever the OPC step is performed on a plurality of layouts, a new OPC result may be accumulated in an OPC library. The generation of the OPC library may cause an increase in efficiency of the OPC step and a gradual reduction in time required for performing OPC.

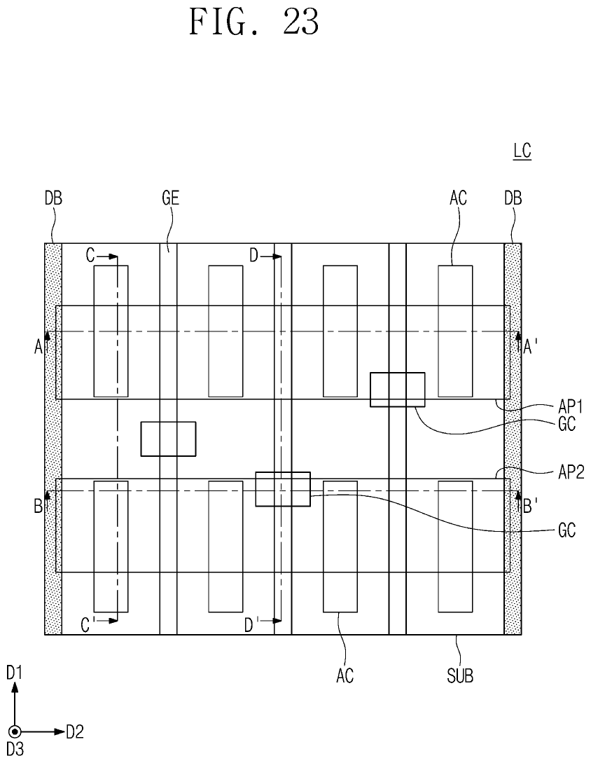

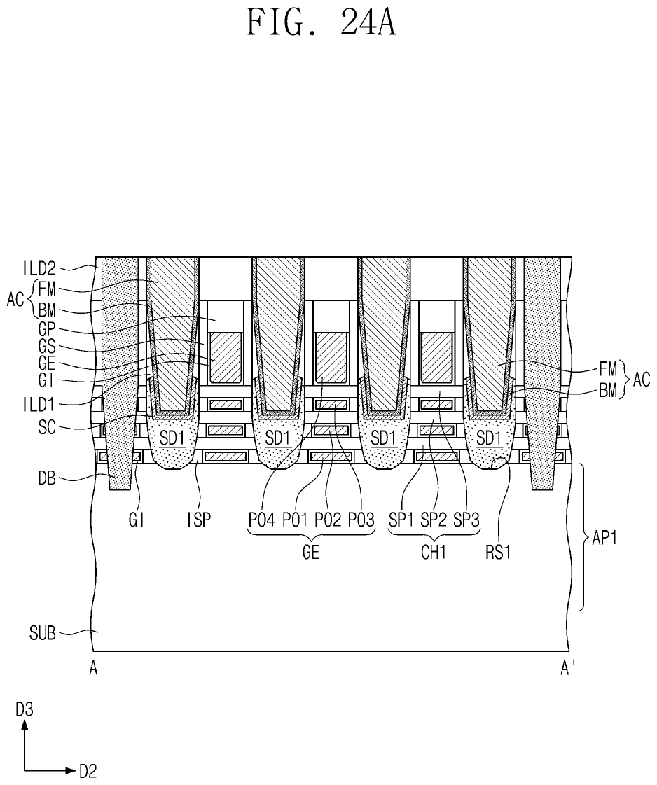

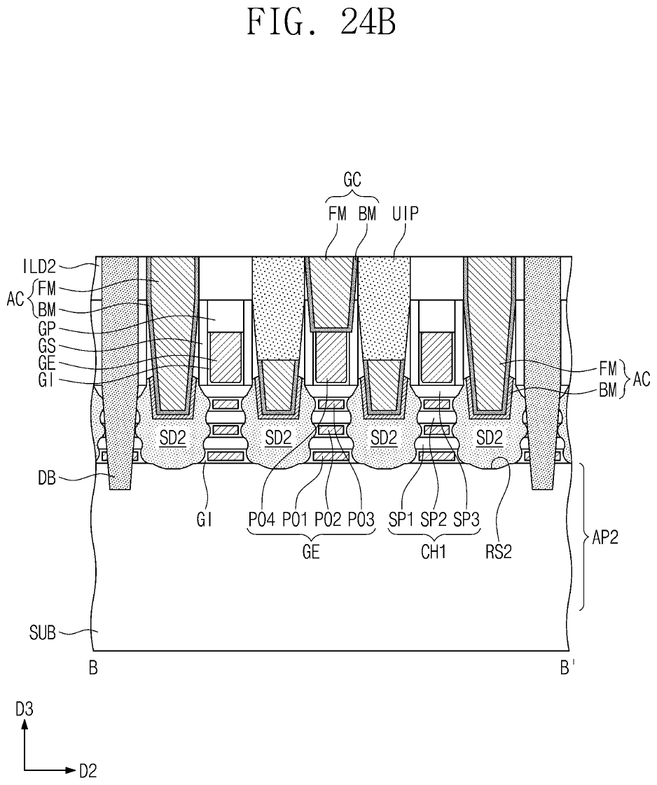

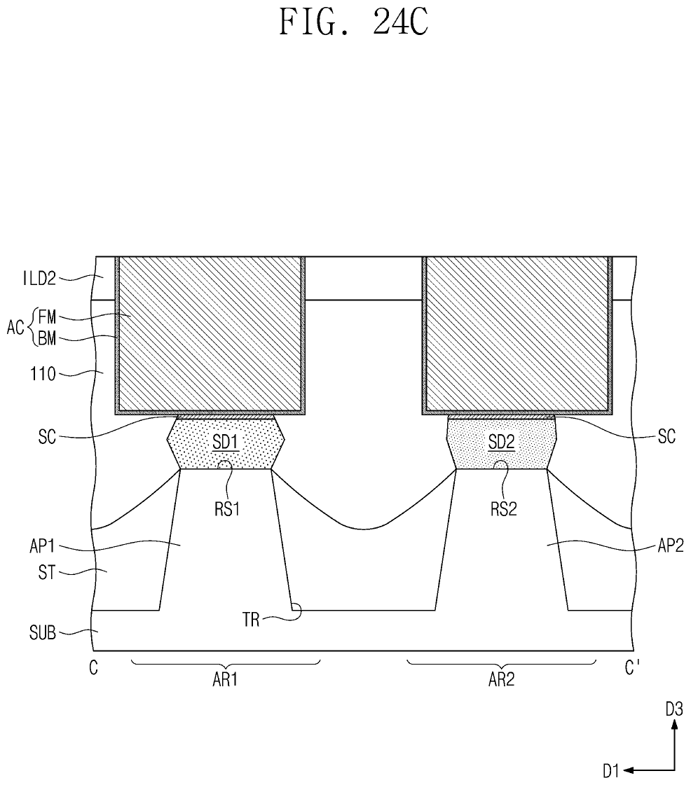

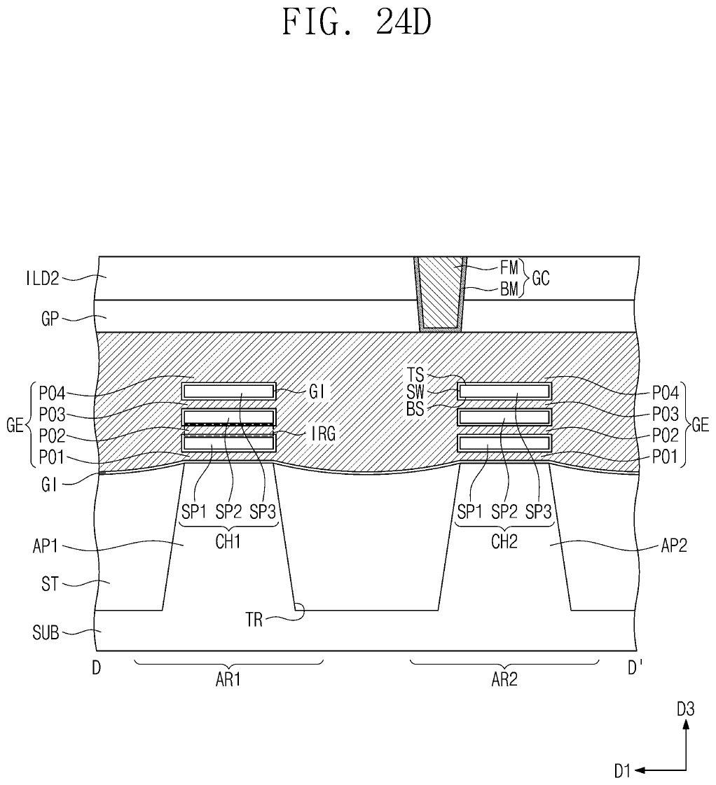

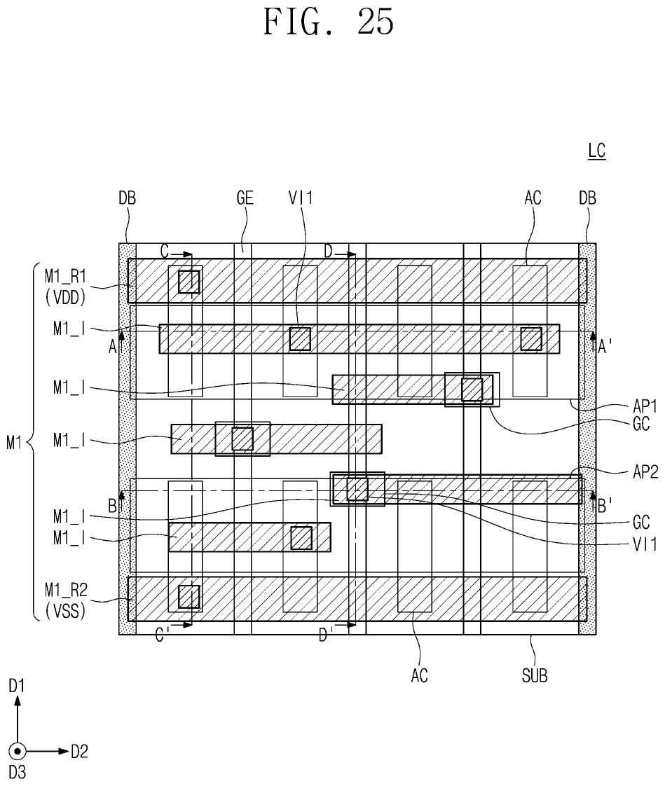

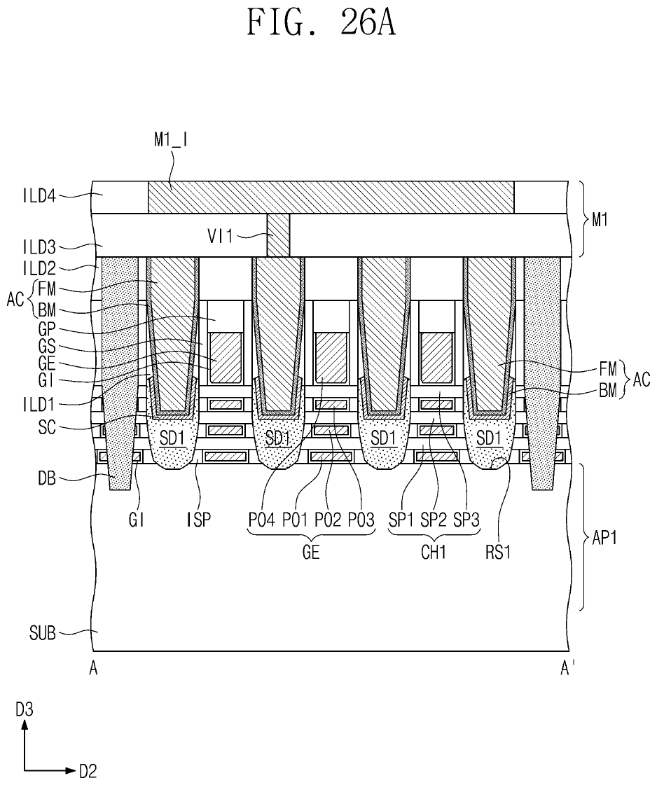

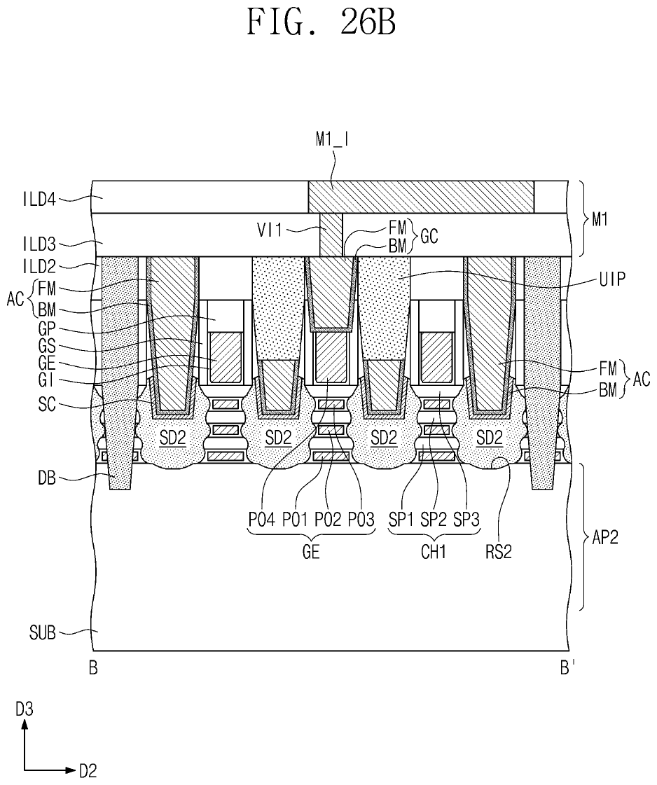

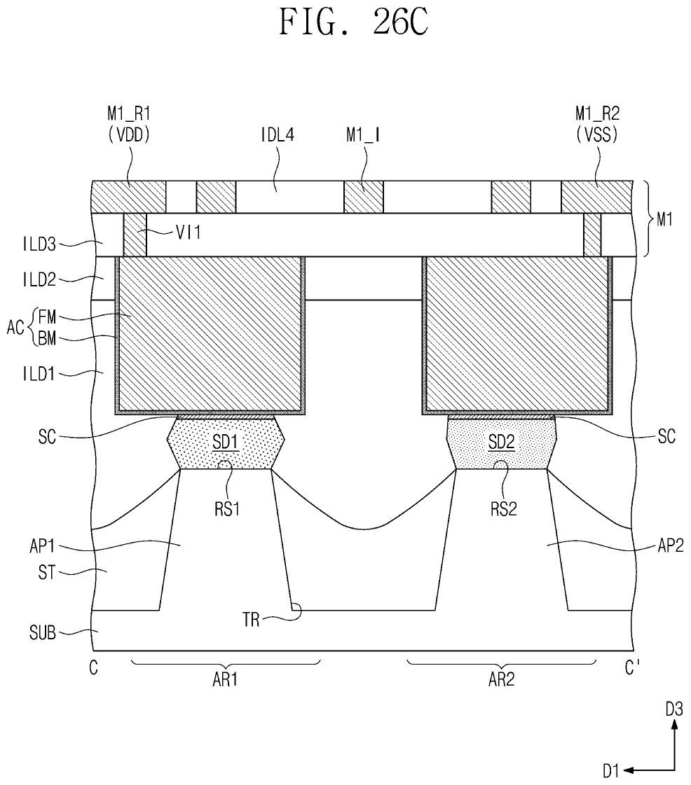

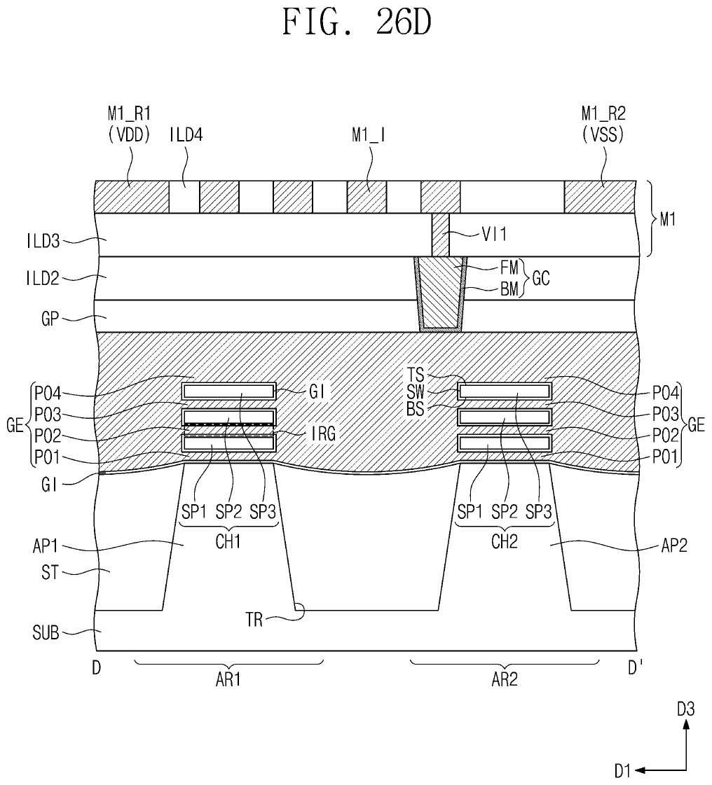

FIGS. 23 and 25 illustrate plan views showing a semiconductor fabrication method according to some embodiments of the present inventive concepts. FIGS. 24A, 24B, 24C, and 24D are cross-sectional views respectively taken along lines A-A′, B-B′, C-C′, and D-D′ of FIG. 23. FIGS. 26A, 26B, 26C, and 26D are cross-sectional views respectively taken along lines A-A′, B-B′, C-C′, and D-D′ of FIG. 25.

Referring to FIGS. 23 and 24A to 24D, a logic cell LC may be provided on a substrate SUB. The logic cell LC may include, for example, logic transistors included in a logic circuit.

A first active pattern AP1 and a second active pattern AP2 may be formed on an upper portion of the substrate SUB. In an embodiment of the present inventive concepts, the first active pattern AP1 may be an NMOSFET region, and the second active pattern AP2 may be a PMOSFET region. The substrate SUB may be a compound semiconductor substrate or a semiconductor substrate including silicon, germanium, or silicon-germanium. For example, the substrate SUB may be a silicon substrate.

The formation of the first active pattern AP1 and the second active pattern AP2 may include forming a trench TR that defines the first and second active patterns AP1 and AP2 on the upper portion of the substrate SUB. The first and second active patterns AP1 and AP2 may be spaced apart from each other in the first direction D1 across the trench TR. The first and second active patterns AP1 and AP2 may each have a linear shape that extends in the second direction D2 intersecting the first direction D1. A device isolation layer ST may be formed to fill the trench TR. The term “fill” (or “filling,” “filled,” or like terms), as may be used herein, is intended to refer broadly to either completely filling a defined space (e.g., trench TR) or partially filling the defined space; that is, the defined space need not be entirely filled but may, for example, be partially filled or have voids or other spaces throughout. The device isolation layer ST may include a silicon oxide layer.

The formation of the first and second active patterns AP1 and AP2 may include forming a hardmask layer on the substrate SUB, forming a plurality of linear photoresist patterns on the hardmask layer, using the photoresist patterns as an etching mask to pattern the hardmask layer, and using the patterned hardmask layer as an etching mask to etch the substrate SUB. The photoresist patterns may be formed by using a photolithography process according to the present inventive concepts discussed above with reference to FIGS. 19 and 20. A photomask for forming the first and second active patterns AP1 and AP2 may be manufactured through a data preparation step (see S30 of FIG. 2) discussed above with reference to FIGS. 4 to 18 according to the present inventive concepts.

First channel patterns CH1 and first source/drain patterns SD1 may be formed on the first active pattern AP1. Each of the first channel patterns CH1 may include a first semiconductor pattern SP1, a second semiconductor pattern SP2, and a third semiconductor pattern SP3 that are sequentially stacked in a third direction D3 perpendicular to the first and second directions D1 and D2, respectively. The first, second, and third semiconductor patterns SP1, SP2, and SP3 may be spaced apart from each other in a vertical direction (i.e., the third direction D3).

Each of the first source/drain patterns SD1 may include an impurity region having a first conductivity type (e.g., n-type). The first source/drain patterns SD1 may be epitaxial patterns formed by a selective epitaxial growth process. For example, the first source/drain patterns SD1 may include the same semiconductor element (e.g., Si) as that of the substrate SUB.

Second channel patterns CH2 and second source/drain patterns SD2 may be formed on the second active pattern AP2. Each of the second channel patterns CH2 may include a first semiconductor pattern SP1, a second semiconductor pattern SP2, and a third semiconductor pattern SP3 that are sequentially stacked in the third direction D3. The first, second, and third semiconductor patterns SP1, SP2, and SP3 may be spaced apart from each other in the third direction D3.

Each of the second source/drain patterns SD2 may include an impurity region having a second conductivity type (e.g., p-type). The second source/drain patterns SD2 may be epitaxial patterns formed by a selective epitaxial growth process. The second source/drain patterns SD2 may include a semiconductor element (e.g., SiGe) whose lattice constant is greater than that of a semiconductor element of the substrate SUB. Therefore, the second source/drain pattern SD2 may provide the second channel pattern CH2 with compressive stress.

Gate electrodes GE may be formed to extend in the first direction D1, while running across the first and second active patterns AP1 and AP2. The gate electrodes GE may be arranged at a regular pitch along a second direction D2. The gate electrode GE may vertically overlap the first and second channel patterns CH1 and CH2.

The gate electrodes GE may be formed by using a photolithography process discussed above according to the present inventive concepts. A photomask for forming the gate electrodes GE may be manufactured through a data preparation step (see S30 of FIG. 2) discussed above with reference to FIGS. 4 to 18 according to the present inventive concepts.

The gate electrode GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

The gate electrode GE may surround a top surface TS, a bottom surface BS, and opposite sidewalls SW of each of the first, second, and third semiconductor patterns SP1, SP2, and SP3. For example, a transistor according to the present embodiment may be a three-dimensional field effect transistor (e.g., MBCFET or GAAFET) in which the gate electrode GE three-dimensionally surrounds the first and second channel patterns CH1 and CH2. The term “surrounds” (or “surround,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

A pair of gate spacers GS may be formed on opposite sidewalls of each of the gate electrodes GE. The gate spacer GS may extend in the first direction D1 along the gate electrode GE. The gate spacer GS may have a top surface higher than that of the gate electrode GE in the third direction D3, with respect to the upper surface of the substrate SUBS. The top surface of the gate spacer GS may be coplanar with that of a first interlayer dielectric layer ILD1 which will be discussed below. The gate spacer GS may include at least one selected from SiCN, SiCON, and SiN. Alternatively, the gate spacers GS may each include a multiple layer formed of at least two materials selected from SiCN, SiCON, and SiN.

A gate capping pattern GP may be formed on each of the gate electrodes GE. The gate capping pattern GP may extend in the first direction D1 along the gate electrode GE. The gate capping pattern GP may include a material having an etch selectivity with respect to first and second interlayer dielectric layers ILD1 and ILD2 which will be discussed below. For example, the gate capping pattern GP may include at least one material selected from SiON, SiCN, SiCON, and SiN.

A gate dielectric layer GI may be formed between the gate electrode GE and the first channel pattern CH1 and between the gate electrode GE and the second channel pattern CH2. The gate dielectric layer GI may cover the top surface TS, the bottom surface BS, and the opposite sidewalls SW of each of the first, second, and third semiconductor patterns SP1, SP2, and SP3 (see FIG. 24D). The term “cover” (or “covered” or “covering,” or like terms), as may be used herein, is intended to broadly refer to a material, layer or structure being on or over another material, layer or structure, but does not require the material, layer or structure to entirely cover the other material, layer or structure, unless specifically stated otherwise.

In an embodiment of the present inventive concepts, the gate dielectric layer GI may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate electrode GE may include a first metal pattern and a second metal pattern on the first metal pattern. The first metal pattern may be provided on the gate dielectric layer GI to constitute the first, second, and third inner electrodes PO1, PO2, and PO3. The first metal pattern may include a work-function metal that controls a threshold voltage of a transistor. A thickness and composition of the first metal pattern may be adjusted to achieve a desired threshold voltage.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). The first metal pattern may further include carbon (C). The first metal pattern may include a plurality of stacked work-function metal layers.

The outer electrode PO4 may include a first metal pattern and a second metal pattern. The second metal pattern may include metal whose resistance is less than that of the first metal pattern. For example, the second metal pattern may include at least one metal selected from tungsten (W), aluminum (Al), titanium (Ti), and tantalum (Ta).

The first interlayer dielectric layer ILD1 may be formed on the substrate SUB. The first interlayer dielectric layer ILD1 may be formed to cover the gate spacers GS, the first source/drain patterns SD1, and the second source/drain pattern SD2. The first interlayer dielectric layer ILD1 may have a top surface substantially coplanar with those of the gate capping patterns GP and those of the gate spacers GS in the third direction D3. The first interlayer dielectric layer ILD1 may be provided thereon with a second interlayer dielectric layer ILD2 that is formed to cover the gate capping patterns GP.

A pair of separation structures DB may be formed to face each other in the second direction D2 on opposite sides of the logic cell LC. The separation structure DB may extend in the first direction D1 parallel to the gate electrodes GE. The separation structure DB may penetrate the first and second interlayer dielectric layers ILD1 and ILD2 to extend into the first and second active patterns AP1 and AP2. The separation structure DB may penetrate (i.e., extend at least partially into) an upper portion of each of the first and second active patterns AP1 and AP2. The separation structure DB may separate an active pattern of the logic cell LC from an active pattern of another logic cell adjacent the logic cell LC.

Active contacts AC may be formed to penetrate the second and first interlayer dielectric layers ILD2 and ILD1 to come into electrical connection with the first and second source/drain patterns SD1 and SD2. Each of the active contacts AC may be provided between a pair of gate electrodes GE.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not explicitly shown, the active contact AC may cover a portion of the top surface of the gate capping pattern GP.

The formation of the active contacts AC may include patterning the first and second interlayer dielectric layers ILD1 and ILD2 to form contact holes, and filling the contact holes with a conductive material. For example, the active contacts AC may be formed by using a photolithography process discussed above according to the present inventive concepts. A photomask for forming the active contacts AC may be manufactured through a data preparation step (see S30 of FIG. 2) discussed above with reference to FIGS. 4 to 18 according to the present inventive concepts.

A silicide pattern SC may be formed between the active contact AC and the first source/drain pattern SD1 and between the active contact AC and the second source/drain pattern SD2. The active contact AC may be electrically connected through the silicide pattern SC to one of the first and second source/drain patterns SD1 and SD2. The silicide pattern SC may include metal silicide, for example, at least one selected from titanium silicide, tantalum silicide, tungsten silicide, nickel silicide, and cobalt silicide.

A gate contact GC may be formed to penetrate the second interlayer dielectric layer ILD2 and the gate capping pattern GP to come into electrical connection with the gate electrode GE. For example, referring to FIG. 24B, the active contact AC may have an upper portion adjacent to the gate contact GC, and an upper dielectric pattern UIP may be formed on the upper portion of the active contact AC. Therefore, it may be possible to prevent the occurrence of a short-circuit caused by contact between the gate contact GC and its adjacent active contact AC.

Each of the active contact AC and the gate contact GC may include a conductive pattern FM and a barrier pattern BM that surrounds the conductive pattern FM. For example, the conductive pattern FM may include at least one metal selected from aluminum, copper, tungsten, molybdenum, and cobalt. The barrier pattern BM may cover sidewalls and a bottom surface of the conductive pattern FM. The barrier pattern BM may include a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

Referring to FIGS. 25 and 26A to 26D, a third interlayer dielectric layer ILD3 may be formed on the second interlayer dielectric layer ILD2. First vias VI1 may be formed in the third interlayer dielectric layer ILD3. A fourth interlayer dielectric layer ILD4 may be formed on the third interlayer dielectric layer ILD3. Wiring lines M1_R1, M1_R2, and M1_I may be formed in the fourth interlayer dielectric layer ILD4. The wiring lines M1_R1, M1_R2, and M1_I may include a first power line M1_R1, a second power line M1_R2, and lower lines M1_I.

Referring back to FIG. 25, the first power line M1_R1 and the second power line M1_R2 may each extend in the second direction D2 while running across the logic cell LC. A plurality of lower lines M1_I may be disposed between the first and second power lines M1_R1 and M1_R2. The plurality of lower lines M1_I may each have a linear or bar shape that extends in the second direction D2 and may be separated from one another in the first direction D1.

A first metal layer M1 may comprise the wiring lines M1_R1, M1_R2, and M1_I and the first vias VI1 thereunder. Each of the first vias VI1 may be interposed between and electrically connect to a wiring line and one of the active contact AC and the gate contact GC. Although not shown, metal layers M2, M3, M4, etc. may be additionally formed on the first metal layer M1.

The first vias VI1 may be formed by using a photolithography process discussed above according to the present inventive concepts. For example, a photomask for forming the first vias VI1 may be manufactured through a data preparation step (see S30 of FIG. 2) discussed above with reference to FIGS. 4 to 18 according to the present inventive concepts.

The wiring lines M1_R1, M1_R2, and M1_I may be formed by using a photolithography process discussed above according to the present inventive concepts. For example, a photomask for forming the wiring lines M1_R1, M1_R2, and M1_I may be manufactured through a data preparation step (see S30 of FIG. 2) discussed above with reference to FIGS. 4 to 18 according to the present inventive concepts.

In an OPC step according to the present inventive concepts, as shape points are employed to implement a free-form correction pattern, it may be possible to increase in accuracy of optical proximity correction (OPC). In an OPC step according to the present inventive concepts, as optical proximity correction (OPC) is selectively performed on a target patch including a unique shape point, it may be possible to maintain consistency of OPC and to remarkably reduce a time required for performing OPC. In the OPC step of the present inventive concepts, efficiency of OPC may increase through the generation of an OPC library.

Although some embodiments of inventive concepts have been discussed with reference to accompanying figures, it will be understood that various changes in form and details may be made therein without departing from the spirit and scope of inventive concepts. It therefore will be understood that the embodiments described above are just illustrative but not limitative in all aspects.

What is claimed is:

1. A semiconductor fabrication method, comprising:
performing optical proximity correction (OPC) on a design pattern of a semiconductor layout to generate a corrected layout; and
forming a photoresist pattern on a substrate by using a photomask manufactured with the corrected layout,
wherein performing the OPC includes:
generating, by at least one processor, a plurality of shape points on a contour of the design pattern;
producing a respective hash value with respect to each of the plurality of shape points;
based on the respective hash value, selecting a first unique shape point from the plurality of shape points, wherein the first unique shape point represents first shape points;
determining a first correction bias of the first unique shape point; and
creating a correction pattern by applying the first correction bias in common to the first shape points,
wherein producing the respective hash value includes:
generating a query range around a target shape point; and
based on geometry analysis in the query range, producing the respective hash value.

2. The semiconductor fabrication method of claim 1, wherein the first shape points have a hash value the same as a hash value of the first unique shape point.

3. The semiconductor fabrication method of claim 1, wherein the first correction bias includes a movement direction and a movement distance of the first shape points from respective original positions of the first shape points.

4. The semiconductor fabrication method of claim 1, wherein performing the OPC further includes:
based on the respective hash value, selecting a second unique shape point from the plurality of shape points, wherein the second unique shape point represents second shape points;
calculating a second correction bias of the second unique shape point; and
applying the second correction bias in common to the second shape points,
wherein the second correction bias is different from the first correction bias.

5. The semiconductor fabrication method of claim 4, wherein
the first shape points have a first hash value,
the second shape points have a second hash value, and
the first hash value and the second hash value are different from each other.

6. The semiconductor fabrication method of claim 1, wherein the performing the OPC further includes accumulating, in an OPC library, the first correction bias of the first unique shape point.

7. The semiconductor fabrication method of claim 1, wherein
the layout includes a plurality of patches, and
the OPC is selectively performed on a target patch among the plurality of patches, the target patch including the first unique shape point.

8. The semiconductor fabrication method of claim 1, wherein
the design pattern has a polygonal shape formed of lines in a first direction and lines in a second direction, the first and second directions being parallel to an upper surface of the substrate, the second direction intersecting the first direction, and
the correction pattern is a free-form correction pattern.

9. The semiconductor fabrication method of claim 1, further comprising performing a mask rule check step on the corrected layout.

10. The semiconductor fabrication method of claim 1, further comprising:
forming a transistor on the substrate;
forming a contact electrically connected to the transistor; and
forming a wiring line on the contact,
wherein the photoresist pattern defines a mask for forming the contact.

11. A semiconductor fabrication method, comprising:
dividing, by a processor, a layout into a plurality of patches;
generating, by the processor, a plurality of shape points in the plurality of patches;
selecting, by the processor, a unique shape point from the plurality of shape points;
selecting, by the processor, a target patch from the plurality of patches, the target patch including the unique shape point;
performing, by the processor, optical proximity correction (OPC) on the target patch to generate a corrected layout; and
forming a photoresist pattern on a substrate by using a photomask manufactured with the corrected layout.

12. The semiconductor fabrication method of claim 11, further comprising:
using the OPC to determine a correction bias of the unique shape point; and
applying the correction bias to a first shape point among the plurality of shape points,
wherein the first shape point has a hash value the same as a hash value of the unique shape point.

13. The semiconductor fabrication method of claim 12, wherein the correction bias includes a movement direction and a movement distance of the first shape point from an original position of the first shape point.

14. The semiconductor fabrication method of claim 11, wherein the plurality of shape points are generated on a contour of a designed pattern in each of the plurality of patches.

15. The semiconductor fabrication method of claim 11, wherein selecting the unique shape point includes:
generating a query range around a target shape point; and
based on geometry analysis in the query range, producing a hash value.

16. An optical proximity correction method, comprising:
performing, by a processor, a first optical proximity correction (OPC) on a first layout;
accumulating, in an OPC library, a first result of the first OPC;
selecting, by the processor, a unique patch from a plurality of patches of a second layout, wherein the first result cannot be applied to the unique patch;
performing a second OPC on the unique patch; and
accumulating, in the OPC library, a second result of the second OPC,
wherein the first result includes a first correction bias with respect to a first unique shape point in the first layout, and
wherein the second result includes a second correction bias with respect to a second unique shape point in the second layout.

17. The optical proximity correction method of claim 16, wherein the plurality of patches of the second layout includes the unique patch and a normal patch that includes the first unique shape point.

18. The optical proximity correction method of claim 16, wherein performing the first OPC includes:
producing a plurality of shape points on a contour of a design pattern in the first layout;
selecting the first unique shape point among the plurality of shape points; and
determining the first correction bias of the first unique shape point.

19. The optical proximity correction method of claim 18, wherein selecting the first unique shape point includes:
generating a query range around a target shape point; and
based on geometry analysis in the query range, producing a hash value.

20. The optical proximity correction method of claim 16, wherein
the first correction bias includes a first movement direction and a first movement distance of the first unique shape point from an original position of the first unique shape point, and
the second correction bias includes a second movement direction and a second movement distance of the second unique shape point from an original position of the second unique shape point.
